(19) United States
(12) Patent Application Publication
(10) Pub. No.: US 2016/0174413 A1
(43) Pub. Date: Jun. 16, 2016

(54) COOLING FOR COMPONENTS OF ELECTRONIC DEVICES

(71) Applicant: Intel Corporation, Santa Clara, CA (US)

(72) Inventor: Robin A. Steinbrecher, Olympia, WA (US)

(21) Appl. No.: 14/571,972

(22) Filed: Dec. 16, 2014

(51) Int. Cl. H05K 7/20

(52) U.S. Cl. CPC H05K 7/20181

(57) ABSTRACT

Apparatuses, methods and storage media associated with cooling one or more heat-generating components of an electronic device upon occurrence of a heat condition are disclosed herein. In embodiments, one or more piezo louvers, or some other cooling zone director, may be used to direct a fan from cooling a first one of the heat-generating components to cooling another one of the heat-generating components. Other embodiments may be described and/or claimed.

### TECHNICAL FIELD

The present disclosure relates to the field of thermal cooling for electronic devices, and specifically to adjustable cooling of heat-generating components in computer server environments.

### BACKGROUND

The background description provided herein is for the purpose of generally presenting the context of the disclosure. Unless otherwise indicated herein, the materials described in this section are not prior art to the claims in this application and are not admitted to be prior art by inclusion in this section.

Electronic devices, e.g., legacy servers, may be designed with redundant cooling to cool one or more heat-generating components of the server such as a processor or memory. For example, a plurality of fans may be organized in a configuration that may have parallel redundancy or series redundancy. Parallel redundancy may refer to the fans being arranged generally in one or more rows with respect to the heat-generating components. Series redundancy may refer to the fans being generally arranged in one or more columns with respect to the heat-generating components. In some embodiments, parallel redundancy may be desirable because it may result in a lower number of fans in the server.

In either parallel or series redundancy configurations, fans in the plurality of fans may be configured to cool different cooling zones or cooling areas of the server. Generally, operation of the server and/or fans may be less than optimal or result in a non-uniform airflow if one of the plurality of fans fails. This non-uniformity may reduce thermal performance and/or computer performance capability of the server or one or more of the heat-generating components of the server. A consequence of this reduced thermal performance may be thermal throttling of one or more of the heat-generating components. Alternatively, in some cases one or more of the heat-generating components may experience an increased workload that may cause the component to output additional or unexpected thermal energy, which may require additional cooling.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates a high-level schematic view of an electronic system with one or more piezo louvers, in accordance with various embodiments.

FIG. 2 illustrates an alternative high-level schematic view of an electronic system with one or more piezo louvers, in accordance with various embodiments.

FIG. 3 illustrates an example process of cooling an electronic system with one or more piezo louvers, in accordance with various embodiments.

FIG. 4 illustrates a high-level schematic view of an electronic system with one or more adjustable cooling zones, in accordance with various embodiments.

FIG. 5 illustrates an example process of cooling an electronic system with one or more adjustable cooling zones, in accordance with various embodiments.

FIG. 6 illustrates an example computer system suitable for use to practice various aspects of the present disclosure, according to the disclosed embodiments.

FIG. 7 illustrates a storage medium having instructions for practicing processes described with references to FIG. 3 or 5, according to disclosed embodiments.

### DETAILED DESCRIPTION

Apparatuses, methods and storage media that are associated with cooling one or more heat-generating components of an electronic device upon occurrence of a heat condition are disclosed herein. In embodiments, one or more piezo louvers may be used to direct a fan from cooling a first one of the heat-generating components to cooling another one of the heat-generating components. In other embodiments, a cooling zone director, which may be a passive stator, a piezo louver, a powered louver, or some other type of cooling zone director, may be used to cause a cooling zone to alternate between a first position and a second position.

As discussed herein, electrical and/or optical components may include components such as processors, central processing units (CPUs), memory such as dynamic random access memory (DRAM), flash memory, dual inline memory modules (DIMMs), logic, a peripheral component interconnect express (PCIe) card, an audio chip, a graphics chip, read-only memory (ROM), a wired or wireless communication chipset, a hard disk drive (HDD), or other components. It will be understood that the above description of electrical and/or optical components is intended as a non-exhaustive list of descriptive examples, and additional or alternative components to those listed above may be used in other embodiments. The electrical and/or optical components may be generically referred to herein as heat-generating components.

In the following detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “module” may refer to, be part of, or include an Application Specific Integrated Circuit (ASIC), an electronic circuit, a processor (shared, dedicated, or group) and/or memory (shared, dedicated, or group) that execute one or more software or firmware programs, a combinational logic circuit, and/or other suitable components that provide the described functionality.

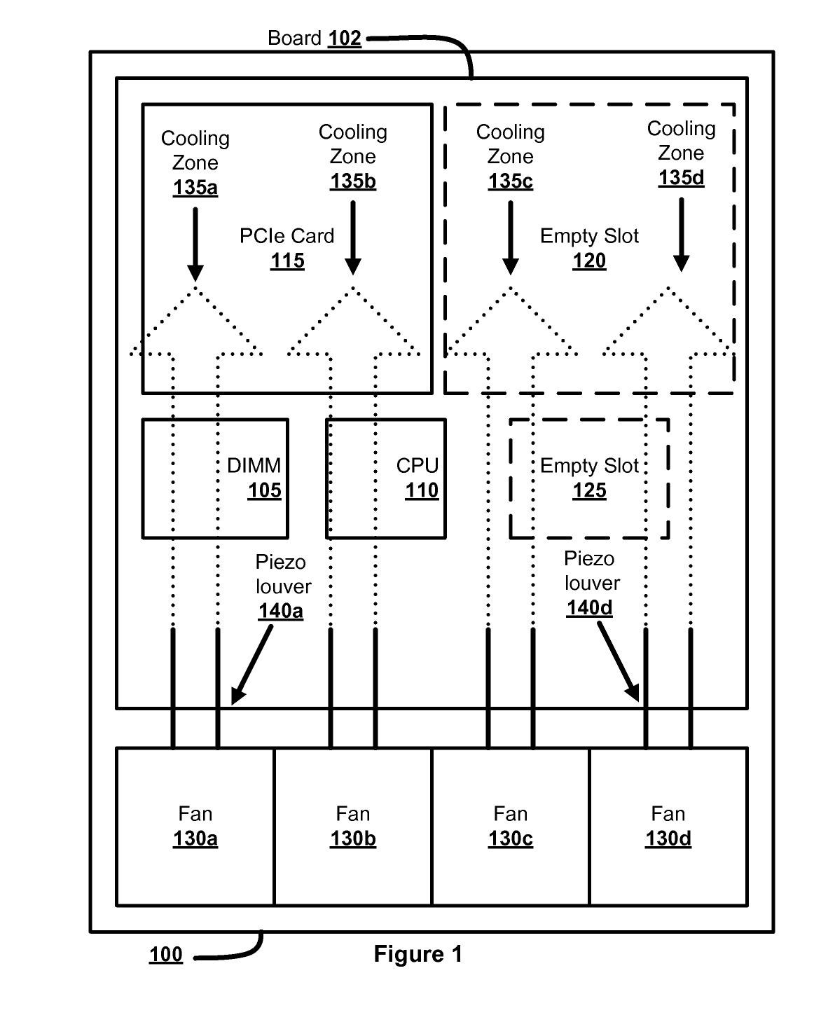

FIG. 1 schematically illustrates an electronic device 100 having a cooling arrangement of the present disclosure, in accordance with various embodiments. In some embodiments, the electronic device 100 may be a server or a server blade in a rack server, while in other embodiments the electronic device 100 may be a smartphone, a tablet computer, an ultrabook, an e-reader, a laptop computer, a desktop computer, a set top box, a digital video recorder, an audio amplifier, and/or a game console. The electronic device 100 may include a circuit board 102. In some embodiments, the circuit board 102 may have one or more heat-generating components coupled with the circuit board 102. For example, in the embodiment depicted in FIG. 1, the circuit board 102 may include a PCIe card 115, a DIMM 105, and a CPU 110. In other embodiments, the heat-generating components may include components such as an audio chip, a graphics chip, DRAM, ROM, a wired or wireless communication chipset, or some other heat-generating component may be coupled with the circuit board 102 either in addition to, or as an alternative to, the components depicted in FIG. 1.

In some embodiments, the circuit board 102 may also include an empty slot such as empty slots 120 and 125. The empty slots 120 and 125 may be slots to which additional heat-generating components may be coupled.

In embodiments, the electronic device 100 may include a plurality of cooling devices such as fans 130a-130d (collectively referred to herein as fans 130). The fans 130 depicted in FIG. 1 may be in a parallel redundancy configuration, as described above. For the sake of clarity, the cooling devices may generally be referred to as fans 130 or cooling fans 130 in the discussion below; however, in other embodiments the cooling device may be a heat sink or some other type of active or passive cooling device. In embodiments, the fans 130 may be configured to move air over one or more of the heat-generating components. For example, in some embodiments the fans 130 may be configured to push or blow air over the heat-generating components, while in other embodiments the fans 130 may be configured to pull or draw air over the heat-generating components. In some embodiments, one or more of the fans 130 may be configured to push air while another of the fans 130 may be configured to draw air. In embodiments where the cooling devices are not fans and are, for example, heat sinks, the cooling devices may be otherwise configured to remove heat from one or more of the heat-generating components by moving air over the heat-generating components or in some other manner.

In some embodiments, the fans 130 may be physically coupled to the board 102, while in other embodiments, the fans 130a-130d may not be physically coupled to the board 102, but may still be configured to move air over or otherwise cool one or more heat-generating components of the board 102. As depicted in FIG. 1, each of the fans 130 may be associated with or generate a different cooling zone 135a, 135b, 135c, or 135d (collectively referred to as cooling zones 135). As used herein, the term “cooling zone” may refer to the region of a device that is cooled due to a specific cooling device such as one of fans 130. Therefore, cooling zone 135a may designate the region of board 102 that is cooled due to fan 130a. It will be understood that although cooling zones 135 are depicted in FIG. 1 as respective arrows with defined borders, the depiction is intended to illustrate the general direction and concept of the cooling zones 135 rather than any specific borders that may be inferred from the specific dimensions of the arrow.

In some embodiments, one or more of the cooling devices, for example, fan 130b, may experience a mechanical fault and operate at less than its full possible capacity, which may mean that components in cooling zone 135b may not be efficiently cooled. In some embodiments, one of the components, for example, the CPU 110, may operate at a increased capacity and the cooling provided by fan 130b may not be sufficient to cool the CPU 110. In some cases, the configuration of the fans 130 and the cooling zones 135 may be based around a worst-case scenario in which the board 102 is coupled with the maximum number of available components, and the components are experiencing a heavy system load. In this worst-case scenario, an even distribution of cooling zones 135 may be desirable. However, in some embodiments such as the embodiment depicted in FIG. 1, the board 102 may not be coupled with the maximum number of available heat-generating components. As discussed herein, the mechanical failure of the cooling device, generation of a hotspot, or alternative arrangement of components on a board 102 may be described as a “heat condition.”

In some embodiments, one or more piezoelectric louvers such as piezoelectric louvers (hereinafter referred to as “piezo louvers”) 140a and 140d may be configured to influence or control the direction and/or coverage (hereinafter jointly described as “direction”) of the cooling zones 135 such as cooling zones 135a and 135d, respectively. Although piezo louvers 140a and 140d are shown to be associated with fans 130a and 130d, piezo louvers may additionally be associated with fans 130b and 130c, though they are not specifically notated as such for the sake of clarity of FIG. 1. Additionally, in some embodiments a single piezo louver may be associated with two or more of fans 130. In embodiments, the piezo louvers 140a and 140d, and other piezo louvers of FIG. 1, may be collectively referred to as piezo louvers 140.

A piezo louver may be a louver that is made of a material that is configured to change shape upon application of an electric charge to the material. Specifically, the piezo louvers 140 may be constructed of a crystalline material that changes shape or orientation upon application of an electric current or charge to the louver 140. The degree or direction to which the piezo louvers 140 change shape may be based on the polarity, intensity, or duration of a current applied to the piezo louvers 140. In some embodiments, the piezo louvers 140 may be coupled with a battery, a DC voltage source, or some other power source that is not shown in FIG. 1 for the sake of clarity. Generally, the piezo louvers 140 may be configured to control the direction of the cooling zones 135 by serving as blades, vents, or some other mechanical configuration that may control or influence airflow either to or from the fans 130.

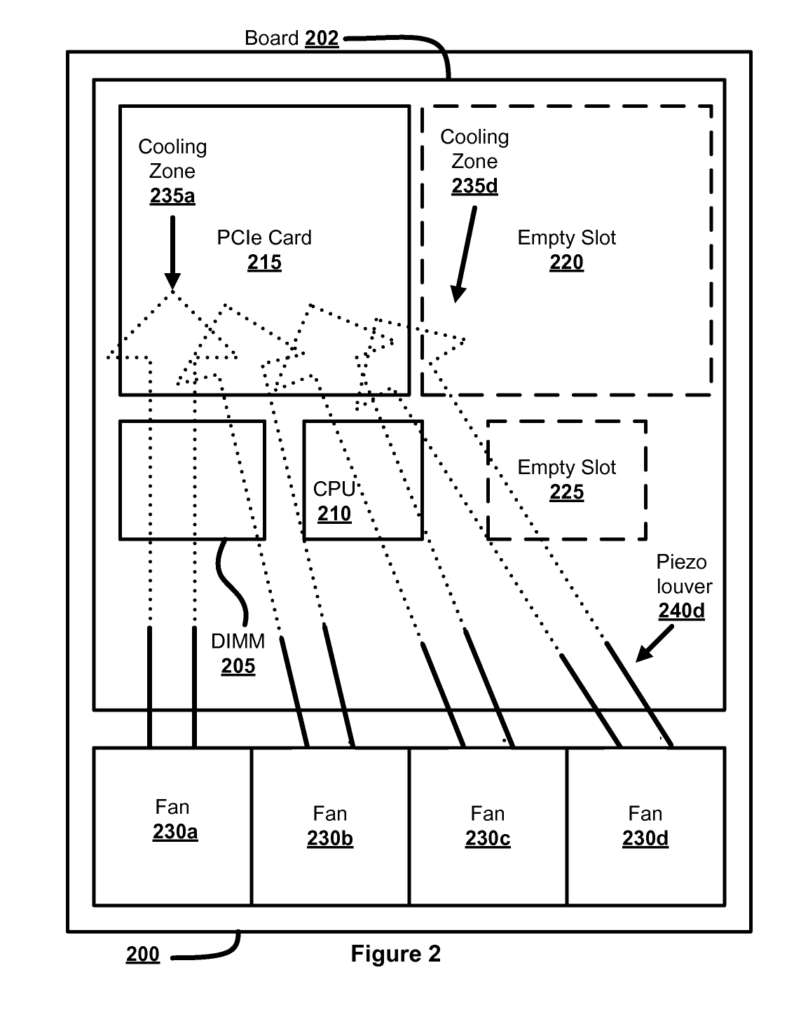

FIG. 2 depicts an embodiment of the electronic device 200 where the piezo louvers have been physically rotated or otherwise adjusted to meet system needs. The electronic device 200 may include a board 202, DIMM 205, CPU 210, PCIe card 215, empty slots 220 and 225, fans 230a-230d (collectively fans 230), cooling zones 235a and 235d (collectively cooling zones 235), and piezo louvers such as piezo louver 240d (collectively piezo louvers 240) which may be respectively similar to electronic device 100, board 102, DIMM 105, CPU 110, PCIe card 115, empty slots 120 and 125, fans 130, cooling zones 135, and piezo louvers 140.

In the embodiment shown in FIG. 2, one or more of the piezo louvers 240 such as piezo louver 240d may have been physically altered such that the cooling zone 235d associated with fan 230d is directed towards PCIe card 215 instead of empty slots 220 and 225. The cooling zones associated with fans 230b and 230c (unlabeled for ease of understanding in FIG. 2) may be similarly altered based on alterations of the piezo louvers associated with fans 230b and 230c. Specifically, an electric current may be applied to one or more of piezo louvers 240 to cause the orientation of one or more of the piezo louvers 240, and therefore the orientation or direction of one or more of the cooling zones 235, to change or rotate.

As shown in FIG. 2, in some embodiments one or more of the piezo louvers such as piezo louver 240d may undergo a greater change than another of the piezo louvers such as the piezo louver associated with fan 230b. Specifically, one or more of the piezo louvers 240 may be subject to an electric current that has a different intensity, duration, polarity, or some other factor than the electric current that is applied to another one of the one or more of the piezo louvers 240. In some embodiments, all of the piezo louvers 240 may be subject to the same electric current and therefore undergo the same direction or orientation shift with respect to the orientation depicted in FIG. 1. The alteration of the piezo louvers 240, and therefore the associated rotation of the cooling zones 235, may allow the fans 230 to more efficiently and quickly cool the components of electronic device 200.

In embodiments, the piezo louvers 240 may be altered to rotate the direction of one or more of the cooling zones 235 to remedy one or more of the other heat conditions discussed above. For example, even if the board 202 has components in empty slots 220 and/or 225, in some embodiments the PCIe card 215 may be operating in a significantly increased capacity, and therefore generating increased heat. In these embodiments, it may be desirable for one or more of the piezo louvers 240 to change the direction of the cooling zone(s) 235 associated with those one or more of the piezo louvers 240 such that the cooling zone(s) 235 are generally directed towards the PCIe card 215. In other embodiments, if, for example, fan 230a experienced mechanical failure, it may be desirable for the piezo louvers 240 to direct the cooling zones 235 to the orientation shown in FIG. 2 to compensate for the cooling zone 235a being reduced or not present.

In some embodiments, the presence of a heat condition may be identified based on a system check for the presence of empty slots such as empty slots 220 or 225. In some embodiments, the presence of a heat condition may be identified based on one or more thermal sensors (not shown for the sake of clarity in FIG. 2) coupled with board 202. In some embodiments, both the piezo louvers 240 and the thermal sensors may be coupled with a controller or controller logic, hereinafter collectively referred to as a “controller” (not shown for the sake of clarity of FIG. 2). The controller may be configured to identify the presence of a heat condition and facilitate rotation of the cooling zones 235 to attempt to remedy the heat condition.

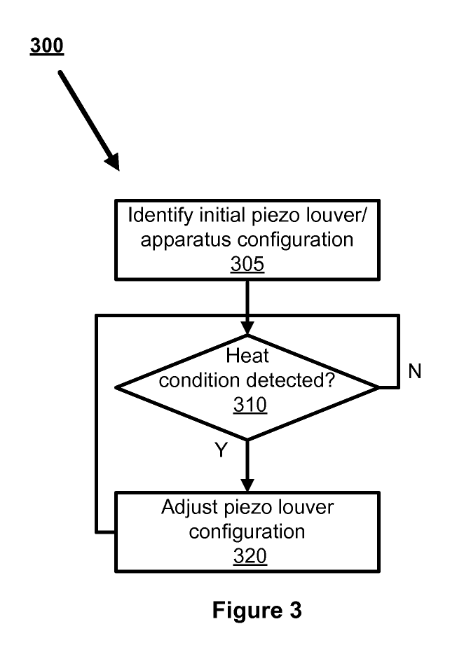

FIG. 3 depicts an example process for remedying the heat condition using the adjustable cooling arrangement shown in FIGS. 1 and 2. Specifically, the process 300 of FIG. 3 may be performed by a controller as described above. In embodiments, the controller may be a process, module, circuitry, chipset, or other component of the electronic device 100 or 200. In embodiments, the controller may be implemented as software, hardware, firmware, or a combination thereof. For example, in some embodiments the CPU 110 may include the controller implemented as firmware, and/or the controller may be implemented as non-transitory computer-executable instructions stored in the DIMM 105.

In some embodiments, the controller may be a baseboard management controller (BMC) or secondary management controller implemented in, on, or communicatively coupled to the electronic device 100 or 200. As noted above, in embodiments the controller may be the hardware of the BMC or secondary management controller, or software/firmware associated with the BMC or secondary management controller. In embodiments, the controller may be responsible for dynamically determining the configuration and/or thermal state of components and/or sensors of electronic devices 100 or 200. In embodiments, the controller may respond to changes in system configuration and/or thermal state with changes in configuration of the fans 130 or 230, as described above.

In other embodiments, the process may be performed by a separate controller process, module, circuitry, chipset, or component of the electronic device 100 or 200 such as a read-only memory (ROM). In some embodiments, the process may be performed by a controller process, module, circuitry, chipset, or component that is separate from, but communicatively coupled with, the electronic device 100 or 200, for example, over a wired or wireless network. Although the electronic device and/or controller are described as a single entity performing certain monitoring or alteration steps, in some embodiments the monitoring and alteration may be performed by a controller associated with different processors or logical modules.

An initial piezo louver and/or apparatus configuration may be detected at 305 by the controller. For example, the apparatus configuration may be identified by the controller based on a system configuration stored in a basic input/output system (BIOS). Specifically, the apparatus configuration may identify a worst case or most common configuration of heat-generating components coupled with a circuit board such as boards 102 or 202. The apparatus configuration may also include an indication of an initial piezo louver configuration. The initial piezo louver configuration may be, for example, the configuration of fans 130 or 230, piezo louvers 140 or 240, and their associated cooling zones 135 or 235.

During operation of the electronic device 100 or 200, the parameters of the electronic device may be monitored at 310. For example, the electronic device, or specifically some logic of the electronic device, may monitor for localized or general thermal increases or decreases, the mechanical status of one or more of the fans, a change in device configuration such as addition or removal of a heat-generating component, or one or more other system parameters.

Specifically, at 310, a determination may be made regarding whether a heat condition is detected. If a heat condition is not detected based on the monitoring of system parameters, then the system parameters may continue to be monitored at 310, as earlier described. However, if a heat condition is detected at 310, for example, the presence of empty slots, a mechanical failure of a fan, a localized hotspot due to a component of the board working at an increased rate, or some other heat condition, then the piezo louver configuration may be adjusted at 320. For example, in one embodiment, the controller may facilitate the movement or rotation of one or more of the piezo louvers 140 or 240, as described above. As described in further detail below, in some embodiments the piezo louvers 140 or 240 may be constantly or periodically moved or rotated (e.g. alternating back and forth). Based on this movement of the piezo louvers 140 or 240, one or more of the cooling zones 135 or 235 associated with respective ones of the fans 130 or 230 may be moved or rotated to a different area or portion of the electronic device or the board of the electronic device, as described above.

On adjustment of the piezo louver configuration, process 300 may return to 310 and continue there from as earlier described. In embodiments, the process 300 may continue until after the electronic system idles or powers down. In other embodiments the process 300 may remain at 320 such that the configuration of the piezo louvers 140 or 240 may be constantly altered or rotated, as described in further detail below.

In some embodiments where a heat condition occurs based on, for example, a failure of a fan 130 or 230 or a component of the board working at an increased rate, the transient thermal response of the component may be relatively long compared to power transients caused by workload variation. For example, time constants for components with or without heat sinks may be in the range of 30 to 60 seconds. Specifically, it may take a component such as a DIMM or a memory between 30 and 60 seconds to generate enough heat that the component would need to be throttled before damage occurred to the component or another component of the electronic device. Because the transient thermal response may be relatively slow, in some embodiments the direction of the airflow, for example, the direction of one or more of the cooling zones, may be changed at a relatively slower rate. Changing the direction of the cooling zones may reduce or eliminate the thermal buildup of the component by averaging the airflow through the server fan zone.

Specifically, a server or electronic device may be a closed-pressure system such that air does not necessarily move in or out of the system, but simply moves throughout the system. By moving the cooling zones over a relatively slow time period, the components may not become significantly hotter, even when one component is generating increased heat or a fan is suffering a mechanical failure. In other embodiments, the server or electronic device may not be a closed-pressure system and so either blowing cooler air onto, or drawing warmer air from, the component or area of the board that is experiencing a heat condition may slow or eliminate the transient thermal response of the component.

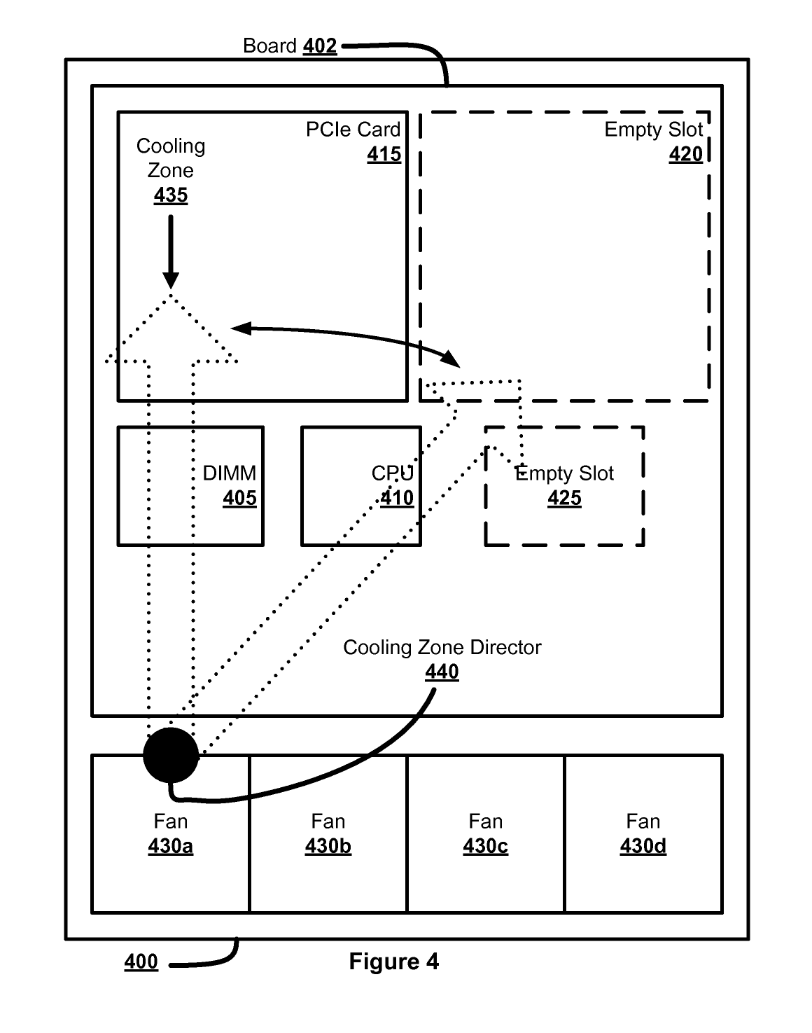

FIG. 4 depicts an embodiment of the electronic device 400 wherein the cooling zones of the electronic device 400 are configured to move upon occurrence of a heat condition such as an increased workload of a component or a fan failure. The electronic device 400 may include a board 402, DIMM 405, CPU 410, PCIe card 415, empty slots 420 and 425, and fans 430a-430d (collectively fans 430), which may be respectively similar to electronic device 100, board 102, DIMM 105, CPU 110, PCIe card 115, empty slots 120 and 125, and fans 130. The electronic device 400 may further include a cooling zone director 440 configured to control a direction or rotation of a cooling zone such as cooling zone 435. As shown in FIG. 4, the cooling zone director 440 may be an element of the fan 430a, while in other embodiments the cooling zone director 440 may be an element of the board 402, or be separate from both the fan 430a and the board 402. Although not shown in FIG. 4 for the sake of clarity, in embodiments one or more of fans 430b, 430c, and 430d may additionally be associated with or generate cooling zones and further be associated with one or more additional cooling zone directors.

In embodiments, the cooling zone director 440 may be configured to rotate, and thereby alter a direction of the cooling zone 435. Specifically, in embodiments the cooling zone director 440 may be configured to rotate between a first position and second position, allowing the cooling zone 435 to rotate between a first position and a second position as shown in FIG. 4 and as described above. For example, in a first position the cooling zone 435 may be directed by the cooling zone director 440 generally toward DIMM 405. In a second position, the cooling zone 435 may be directed by the cooling zone director 440 generally toward empty slot 420. The different positions depicted in FIG. 4 are for the sake of example, and in other embodiments the positions of the cooling zone 435 may be different than shown in FIG. 4. By alternating the orientation of the cooling zone director 440, and therefore the orientation of the cooling zone 435 between the first and second positions, the thermal buildup of a component based on an increased workload of the component, a mechanical fan failure, or another heat condition, may be reduced or eliminated as described above.

In embodiments, the cooling zone director 440 may be a slowly rotating stator with one or more directional louvers. In embodiments, the stator may be passive, and may be driven by the airflow from one or more of the fans 430 that are not experiencing a mechanical failure. Specifically, the electronic device may be a closed-pressure system as discussed above. When one or more of the fans 430 experience a mechanical failure, a low-pressure area may result where there is reduced or no airflow. The pressure in the closed-pressure system may change and the resultant change may cause the passive stator to rotate such that cooling zone 435 shifts to provide cooling to the low-pressure area. Because the electronic device 400 may be a closed-pressure system, the shift in the orientation of the cooling zone 435 may generate a new or different low-pressure area, which may cause the passive stator to continue to rotate or otherwise change orientation. In embodiments, the slowly rotating stator may thereby periodically move the direction of the cooling zone 435 between the first position and the second position without the use of a powered mechanism such as a motor or a drivetrain. In some embodiments, the stator may be locked in the first position until such time as the controller identifies a heat condition, at which point the stator may become unlocked and allowed to rotate between the first and second positions.

In an alternative embodiment, the cooling zone director 440 may be one or more powered louvers that change direction periodically. For example, the cooling zone director 440 may be implemented as one or more louvers that are coupled with a motor or drivetrain and continually changes the direction of the louvers between a first position and a second position, and the resultant direction or orientation of the cooling zone 435 between a first position and a second position. In embodiments, the direction of the cooling zone 435 may change as a constant or semi-constant sweep between the first position and the second position depicted in FIG. 4 so that the cooling zone 435 also passes over areas of the board 402 that are between the first and the second positions. In other embodiments, the direction of the cooling zone 435 may change as periodic switches between the first position and the second position so that the cooling zone 435 spends little to no time cooling the areas of the board 402 that are between the first and second positions.

In some embodiments, the cooling zone 435 may be switched between the first position and the second position without detection of a heat condition, whereas in other embodiments the cooling zone 435 may be switched between the first position and the second position only upon detection of a heat condition. In embodiments, if the electronic device 400 includes a plurality of cooling zone directors 440 implemented as a plurality of powered louvers, in some embodiments the plurality of powered louvers may all be switched with the same periodicity, the same rate, or the same orientation, whereas in other embodiments one or more of the plurality of powered louvers may be switched with a periodicity, rate, or orientation that is different than another of the plurality of powered louvers.

In an alternative embodiment, the cooling zone director 440 may be a piezo louver such as piezo louvers 140. In embodiments, the piezo louver may be activated periodically to alter the cooling zone 435 between the first position and the second position. In embodiments, the cooling zone 435 may be switched between the first position and the second position every 5 to 10 seconds, though in other embodiments different time periods may be used.

In some embodiments, the cooling zone 435 may be switched between the first position and the second position without detection of a heat condition, whereas in other embodiments the cooling zone 435 may be switched between the first position and the second position only upon detection of a heat condition. As discussed above, if the electronic device 400 includes a plurality of cooling zone directors 440 implemented as a plurality of piezo louvers, in some embodiments the plurality of piezo louvers may all be switched with the same periodicity or the same orientation, whereas in other embodiments one or more of the plurality of piezo louvers may be switched with a periodicity or orientation that is different than another of the plurality of piezo louvers.

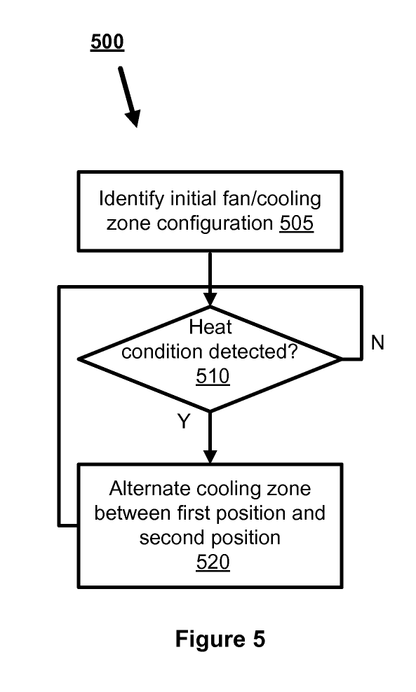

FIG. 5 depicts an example process that may be performed for alternating the position of a cooling zone such as cooling zone 435. Similar to process 300, the operations of process 500 may be performed by a controller or other like elements earlier described. Specifically, an initial configuration of one or more of the fans 430 and or the cooling zone(s) 435 may be identified at 505. Thereafter, a heat condition, such as an increased workload of a component of the electronic device 400, a failure of one or more of the fans 430, or some other heat condition, may be monitored, at 510. If the heat condition is not detected, the monitoring may continue at 510. If the heat condition is detected, the cooling zone 435 may be caused to alternate between the first position and the second position as shown in FIG. 4 at 520. In embodiments, a controller of the electronic system may be configured to alternate the cooling zone 435 between the first position and second position through activation of a powered louver or a piezo louver, as described above. In other embodiments, the controller may be configured to alternate the cooling zone 435 between the first position and the second position by allowing a passively powered stator to rotate the cooling zone 435 between the first position and the second position, as described above. On alternating the cooling zone 435, process 500 may return to 510 and continues there from as earlier described. In embodiments, the process 500 may continue until after the electronic system idles or powers down.

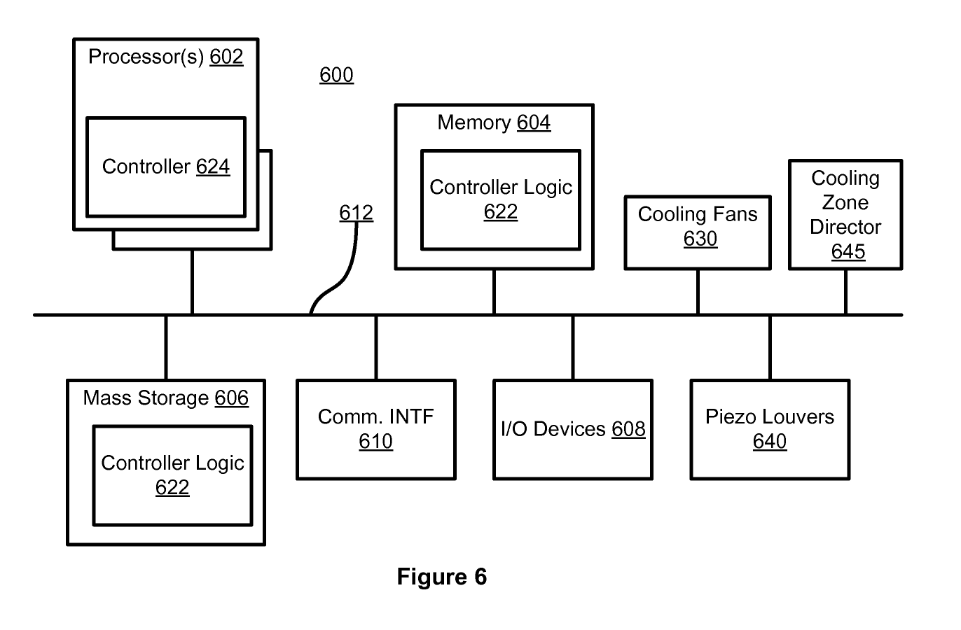

FIG. 6 illustrates an example electronic device 600 (e.g., a computer, a server, or some other electronic device) that may be suitable to practice selected aspects of the present disclosure. As shown, electronic device 600 may include one or more processors or processor cores 602 and system memory 604. For the purpose of this application, including the claims, the terms “processor” and “processor cores” may be considered synonymous, unless the context clearly requires otherwise. Additionally, electronic device 600 may include mass storage devices 606 (such as diskette, hard drive, compact disc read-only memory (CD-ROM) and so forth), input/output (I/O) devices 608 (such as display, keyboard, cursor control and so forth) and communication interfaces 610 (such as network interface cards, modems and so forth). The elements may be coupled to each other via system bus 612, which may represent one or more buses. In the case of multiple buses, they may be bridged by one or more bus bridges (not shown). In embodiments, the elements may be organized into different earlier described cooling zones (not shown). Additionally, or alternatively, electronic device 600 may also include one or more cooling fans 630, one or more piezo louvers 640, and one or more cooling zone directors 645, which may be respectively similar to cooling fans 130, 230, or 430, piezo louvers 140 or 240, or cooling zone director 440. In embodiments, the processor(s) 602 may be or include one or more of the controllers 624 configured to perform the operations described above with respect to FIG. 3 or 5.

Each of these elements may perform its conventional functions known in the art. In particular, in some embodiments, system memory 604 and mass storage devices 606 may be employed to store a working copy and a permanent copy of the programming instructions configured to cooperate with controllers 624 to perform the operations associated with the cooling processes of FIG. 3 or 5, earlier described, collectively referred to as controller logic 622. The various elements may be implemented by assembler instructions supported by processor(s) 602 or high-level languages, such as, for example, C, that can be compiled into such instructions.

The number, capability and/or capacity of these elements 610-612 may vary, depending on whether electronic device 600 is used as a blade in a rack server, as a stand-alone server, or as some other type of electronic device such as a client device. When used as a client device, the capability and/or capacity of these elements 610-612 may vary, depending on whether the client device is a stationary or mobile device, like a smartphone, computing tablet, ultrabook or laptop. Otherwise, the constitutions of elements 610-612 may be known, and accordingly will not be further described. When used as a server device, the capability and/or capacity of these elements 610-612 may also vary, depending on whether the server is a single stand-alone server or a configured rack of servers or a configured rack of server elements.

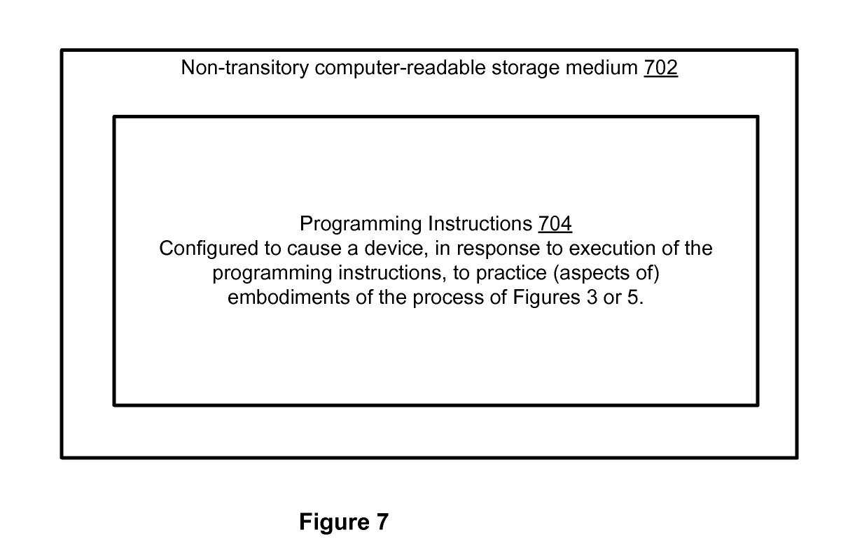

As will be appreciated by one skilled in the art, the present disclosure may be embodied as methods or computer program products. Accordingly, the present disclosure, in addition to being embodied in hardware or logic as earlier described, may take the form of an entire software embodiment (including firmware, resident software, micro-code, etc.) or an embodiment combining software and hardware aspects that may all generally be referred to as a “circuit,” “module” or “system.” Furthermore, the present disclosure may take the form of a computer program product embodied in any tangible or non-transitory medium of expression having computer-usable program code embodied in the medium. FIG. 7 illustrates an example computer-readable non-transitory storage medium that may be suitable for use to store instructions that cause an apparatus, in response to execution of the instructions by the apparatus, to practice selected aspects of the present disclosure. As shown, non-transitory computer-readable storage medium 702 may include a number of programming instructions 704. Programming instructions 704 may be configured to enable a device, e.g., electronic device 600, in response to execution of the programming instructions, to perform, e.g., various operations associated with the adjustable cooling processes of FIG. 3 or 5. In alternate embodiments, programming instructions 704 may be disposed on multiple computer-readable non-transitory storage media 702 instead. In alternate embodiments, programming instructions 704 may be disposed on computer-readable transitory storage media 702, such as signals.

Any combination of one or more computer-usable or computer-readable medium(s) may be utilized. The computer-usable or computer-readable medium may be, for example, but is not limited to, an electronic, magnetic, optical, electromagnetic, infrared, or semiconductor system, apparatus, device, or propagation medium. More specific examples (a non-exhaustive list) of the computer-readable medium would include the following: an electrical connection having one or more wires, a portable computer diskette, a hard disk, a random access memory (RAM), a read-only memory (ROM), an erasable programmable read-only memory (EPROM or flash memory), an optical fiber, a portable compact disc read-only memory (CD-ROM), an optical storage device, a transmission media such as those supporting the Internet or an intranet, or a magnetic storage device. Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory. In the context of this document, a computer-usable or computer-readable medium may be any medium that can contain, store, communicate, propagate, or transport the program for use by or in connection with the instruction execution system, apparatus, or device. The computer-usable medium may include a propagated data signal with the computer-usable program code embodied therewith, either in baseband or as part of a carrier wave. The computer-usable program code may be transmitted using any appropriate medium, including but not limited to wireless, wireline, optical fiber cable, radio frequency (RF), etc.

Computer program code for carrying out operations of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The present disclosure is described with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer-readable medium that can direct a computer or other programmable data processing apparatus to function in a particular manner, such that the instructions stored in the computer-readable medium produce an article of manufacture including instruction means that implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions that execute on the computer or other programmable apparatus provide processes for implementing the functions/acts specified in the flowchart and/or block diagram block or blocks.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The terminology used herein is for the purpose of describing particular embodiments only and is not intended to be limiting of the disclosure. As used herein, the singular forms “a,” “an” and “the” are intended to include plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments may be implemented as a computer process, a computing system or as an article of manufacture such as a computer program product of computer-readable media. The computer program product may be a computer storage medium readable by a computer system and encoding computer program instructions for executing a computer process.

The corresponding structures, material, acts, and equivalents of all means or steps plus function elements in the claims below are intended to include any structure, material or act for performing the function in combination with other claimed elements that are specifically claimed. The description of the present disclosure has been presented for purposes of illustration and description, but is not intended to be exhaustive or limited to the disclosure in the form disclosed. Many modifications and variations will be apparent to those of ordinary skill without departing from the scope and spirit of the disclosure. The embodiment was chosen and described in order to best explain the principles of the disclosure and the practical application, and to enable others of ordinary skill in the art to understand the disclosure for embodiments with various modifications as are suited to the particular use contemplated.

Referring back to FIG. 6, for one embodiment, at least one of processors 602, and specifically the controller 624, may be packaged together with memory having controller logic 622 (in lieu of storing on memory 604 and storage 606). For one embodiment, at least one of processors 602 may be packaged together with memory having controller logic 622 to form a System in Package (SiP). For one embodiment, at least one of processors 602 may be integrated on the same die with memory having controller logic 622. For one embodiment, at least one of processors 602 may be packaged together with memory having controller logic 622 to form a System on Chip (SoC). For at least one embodiment, the SoC may be utilized in, e.g., but not limited to, a smartphone or computing tablet.

Thus various example embodiments of the present disclosure have been described including, but not limited to:

Example 1 may include a system comprising: a plurality of heat-generating components; a plurality of fans to move air over the plurality of heat-generating components via respective piezoelectric louvers; and a controller coupled with a piezoelectric louver of the respective piezoelectric louvers, the controller to control the piezoelectric louver to move from a first position where the first one of the plurality of fans causes air to move over a first one of the plurality of heat-generating components to a second position where the first one of the plurality of fans causes air to move over a second one of the plurality of heat-generating components.

Example 2 may include the system of example 1, wherein the controller is to control the piezoelectric louver to move based on detection of a heat condition associated with the second one of the plurality of heat-generating components.

Example 3 may include the system of example 2, wherein the heat condition is an increased workload of the second one of the plurality of heat-generating components.

Example 4 may include the system of example 3, wherein the heat condition is a failure of a second one of the plurality of fans that is associated with the second one of the plurality of heat-generating components.

Example 5 may include the system of any of examples 1-4, wherein the system is a server.

Example 6 may include the system of any of examples 1-4, further comprising a circuit board having the plurality of heat-generating components disposed thereon.

Example 7 may include an electronic device comprising: a plurality of heat-generating components; a fan to move air over the plurality of heat-generating components via a cooling zone director; and a controller coupled with the cooling zone director to control the cooling zone director to alternate between a first position where the fan is to move air over a first component of the plurality of heat-generating components and a second position where the fan is to move air over a second component of the plurality of heat-generating components.

Example 8 may include the electronic device of example 7, wherein the controller is to control the cooling zone director to alternate between the first position and the second position based on an air pressure differential of the electronic device.

Example 9 may include the electronic device of example 7, wherein the controller is to control the cooling zone director to alternate between the first position and the second position based on a detection of a heat condition associated with the second component.

Example 10 may include the electronic device of example 9, wherein the heat condition is an increased workload of the second component.

Example 11 may include the electronic device of example 9, wherein the fan is a first fan and the heat condition is a failure of a second fan that is associated with the second component.

Example 12 may include the electronic device of any of examples 7-11, wherein the electronic device is a server.

Example 13 may include the electronic device of any of examples 7-11, further comprising a circuit board having the plurality of heat-generating components disposed thereon.

Example 14 may include the electronic device of any of examples 7-11, wherein the controller is to control the cooling zone director alternate between the first position and the second position with a frequency that is greater than a thermal time constant related to the first component.

Example 15 may include the electronic device of any of examples 7-11, wherein the cooling zone director includes a piezoelectric louver.

Example 16 may include the electronic device of any of examples 7-11, wherein the controller is to control the cooling zone director to continually alternate between the first position and the second position.

Example 17 may include the electronic device of any of examples 7-11, wherein the controller is to control the cooling zone director to periodically alternate between the first position and the second position.

Example 18 may include a method comprising: identifying, by a circuit communicatively coupled with a plurality of fans, a heat condition associated with a heat-generating component of a plurality of heat-generating components; and activating, by the circuit based on the identifying of the heat condition, a piezoelectric louver to cause a fan of the plurality of fans to cause air to move over the heat-generating component.

Example 19 may include the method of example 18, wherein identifying a heat condition comprises identifying an increased workload of the heat-generating component.

Example 20 may include the method of examples 18 or 19, wherein the fan is a first fan of the plurality of fans, and wherein identifying a heat condition comprises identifying a failure of a second one of the plurality of fans that is associated with the heat-generating component.

Example 21 may include one or more non-transitory computer-readable media comprising instructions to cause an electronic device, upon execution of the instructions by a controller of the electronic device, to: identify a heat condition associated with a first heat-generating component of a plurality of heat-generating components; and alternate, based on the heat condition, a cooling zone director between a first position associated with the first heat-generating component and a second position associated with a second heat-generating component of the plurality of heat-generating components with a frequency that is greater than a thermal time constant related to the first heat-generating component.

Example 22 may include the one or more non-transitory computer-readable media of example 21, wherein a fan is to cause air to move over the first heat-generating component when the cooling zone director is in the first position and the fan is to cause air to move over the second heat-generating component when the cooling zone director is in the second position.

Example 23 may include the one or more non-transitory computer-readable media of example 22, wherein the fan is a first fan and the heat condition is a failure of a second fan that is associated with the second one of the plurality of heat-generating components.

Example 24 may include the one or more non-transitory computer-readable media of any of examples 21-23, wherein the electronic device is caused to alternate the cooling zone director from the first position to the second position based on an air pressure differential of the electronic device.

Example 25 may include the one or more non-transitory computer-readable media of any of examples 21-23, wherein the electronic device is caused to identify a heat condition associated with an increased workload of the second heat-generating component.

Example 26 may include the one or more non-transitory computer-readable media of any of examples 21-23, wherein the electronic device is a server.

Example 27 may include the one or more non-transitory computer-readable media of any of examples 21-23, wherein the cooling zone director includes a piezoelectric louver.

Example 28 may include the one or more non-transitory computer-readable media of any of examples 21-23, wherein the instructions are further to control the cooling zone director to continually alternate between the first position and the second position.

Example 29 may include the one or more non-transitory computer-readable media of any of examples 21-23, wherein the instructions are further to control the cooling zone director to periodically alternate between the first position and the second position.

Example 30 may include one or more non-transitory computer-readable media comprising instructions to cause an electronic device, upon execution of the instructions by one or more processors of the electronic device, to: identify, by a circuit communicatively coupled with a plurality of fans, a heat condition associated with a heat-generating component of a plurality of heat-generating components; and activate, by the circuit based on the identifying of the heat condition, a piezoelectric louver to cause a fan of the plurality of fans to cause air to move over the heat-generating component.

Example 31 may include the one or more non-transitory computer-readable media of example 30, wherein the instructions to identify a heat condition include instructions to identify an increased workload of the heat-generating component.

Example 32 may include the one or more non-transitory computer-readable media of examples 30 or 31, wherein the fan is a first fan of the plurality of fans, and wherein the instructions to identify a heat condition include instructions to identify a failure of a second one of the plurality of fans that is associated with the heat-generating component.

Example 33 may include an apparatus comprising: means to identify, by a circuit communicatively coupled with a plurality of fans, a heat condition associated with a heat-generating component of a plurality of heat-generating components; and means to activate, by the circuit based on the identifying of the heat condition, a piezoelectric louver to cause a fan of the plurality of fans to cause air to move over the heat-generating component.

Example 34 may include the apparatus of example 33, wherein the means to identify a heat condition include means to identify an increased workload of the heat-generating component.

Example 35 may include the apparatus of examples 33 or 34, wherein the fan is a first fan of the plurality of fans, and wherein the means to identify a heat condition include means to identify a failure of a second one of the plurality of fans that is associated with the heat-generating component.

Example 36 may include an apparatus comprising: means to identify a heat condition associated with a first heat-generating component of a plurality of heat-generating components; and means to alternate, based on the heat condition, a cooling zone director between a first position associated with the first heat-generating component and a second position associated with a second heat-generating component of the plurality of heat-generating components with a frequency that is greater than a thermal time constant related to the first heat-generating component.

Example 37 may include the apparatus of example 36, wherein a fan is to cause air to move over the first heat-generating component when the cooling zone director is in the first position and the fan is to cause air to move over the second heat-generating component when the cooling zone director is in the second position.

Example 38 may include the apparatus of example 37, wherein the fan is a first fan and the heat condition is a failure of a second fan that is associated with the second one of the plurality of heat-generating components.

Example 39 may include the apparatus of any of examples 36-38, further comprising means to alternate the cooling zone director from the first position to the second position based on an air pressure differential of the electronic device.

Example 40 may include the apparatus of any of examples 36-38, further comprising means to identify a heat condition associated with an increased workload of the second heat-generating component.

Example 41 may include the apparatus of any of examples 36-38, wherein the electronic device is a server.

Example 42 may include the apparatus of any of examples 36-38, wherein the cooling zone director includes a piezoelectric louver.

Example 43 may include the apparatus of any of examples 36-38, further comprising means to control the cooling zone director to continually alternate between the first position and the second position.

Example 44 may include the apparatus of any of examples 36-38, further comprising means to control the cooling zone director to periodically alternate between the first position and the second position.

Example 45 may include a method comprising: identifying, by a controller of an electronic device, a heat condition associated with a first heat-generating component of a plurality of heat-generating components of the electronic device; and alternating, by the controller based on the heat condition, a cooling zone director between a first position associated with the first heat-generating component and a second position associated with a second heat-generating component of the plurality of heat-generating components with a frequency that is greater than a thermal time constant related to the first heat-generating component.

Example 46 may include the method of example 45, wherein a fan is to cause air to move over the first heat-generating component when the cooling zone director is in the first position and the fan is to cause air to move over the second heat-generating component when the cooling zone director is in the second position.

Example 47 may include the method of example 46, wherein the fan is a first fan and the heat condition is a failure of a second fan that is associated with the second one of the plurality of heat-generating components.

Example 48 may include the method of any of examples 45-47, further comprising alternating, by the controller, the cooling zone director from the first position to the second position based on an air pressure differential of the electronic device.

Example 49 may include the method of any of examples 45-47, further comprising identifying, by the controller, a heat condition associated with an increased workload of the second heat-generating component.

Example 50 may include the method of any of examples 45-47, wherein the electronic device is a server.

Example 51 may include the method of any of examples 45-47, wherein the cooling zone director includes a piezoelectric louver.

Example 52 may include the method of any of examples 45-47, further comprising controlling, by the controller, the cooling zone director to continually alternate between the first position and the second position.

Example 53 may include the method of any of examples 45-47, further comprising controlling, by the controller, the cooling zone director to periodically alternate between the first position and the second position.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

What is claimed is:

1. A system comprising:
a plurality of heat-generating components;
a plurality of fans to move air over the plurality of heat-generating components via respective piezoelectric louvers; and
a controller coupled with a piezoelectric louver of the respective piezoelectric louvers, the controller to control the piezoelectric louver to move from a first position where the first one of the plurality of fans causes air to move over a first one of the plurality of heat-generating components to a second position where the first one of the plurality of fans causes air to move over a second one of the plurality of heat-generating components.

2. The system of claim 1, wherein the controller is to control the piezoelectric louver to move based on detection of a heat condition associated with the second one of the plurality of heat-generating components.

3. The system of claim 2, wherein the heat condition is an increased workload of the second one of the plurality of heat-generating components.

4. The system of claim 3, wherein the heat condition is a failure of a second one of the plurality of fans that is associated with the second one of the plurality of heat-generating components.

5. The system of claim 1, wherein the system is a server.

6. The system of claim 1, further comprising a circuit board having the plurality of heat-generating components disposed thereon.

7. An electronic device comprising:
a plurality of heat-generating components;
a fan to move air over the plurality of heat-generating components via a cooling zone director; and
a controller coupled with the cooling zone director to control the cooling zone director to alternate between a first position where the fan is to move air over a first component of the plurality of heat-generating components and a second position where the fan is to move air over a second component of the plurality of heat-generating components.

8. The electronic device of claim 7, wherein the controller is to control the cooling zone director to alternate between the first position and the second position based on an air pressure differential of the electronic device.

9. The electronic device of claim 7, wherein the controller is to control the cooling zone director to alternate between the first position and the second position based on a detection of a heat condition associated with the second component.

10. The electronic device of claim 9, wherein the heat condition is an increased workload of the second component.

11. The electronic device of claim 9, wherein the fan is a first fan and the heat condition is a failure of a second fan that is associated with the second component.

12. The electronic device of claim 7, wherein the electronic device is a server.

13. The electronic device of claim 7, further comprising a circuit board having the plurality of heat-generating components disposed thereon.

14. The electronic device of claim 7, wherein the controller is to control the cooling zone director alternate between the first position and the second position with a frequency that is greater than a thermal time constant related to the first component.

15. The electronic device of claim 7, wherein the cooling zone director includes a piezoelectric louver.

16. The electronic device of claim 7, wherein the controller is to control the cooling zone director to continually alternate between the first position and the second position.

17. The electronic device of claim 7, wherein the controller is to control the cooling zone director to periodically alternate between the first position and the second position.

18. A method comprising:
identifying, by a circuit communicatively coupled with a plurality of fans, a heat condition associated with a heat-generating component of a plurality of heat-generating components; and
activating, by the circuit based on the identifying of the heat condition, a piezoelectric louver to cause a fan of the plurality of fans to cause air to move over the heat-generating component.

19. The method of claim 18, wherein identifying a heat condition comprises identifying an increased workload of the heat-generating component.

20. The method of claim 18, wherein the fan is a first fan of the plurality of fans, and wherein identifying a heat condition comprises identifying a failure of a second one of the plurality of fans that is associated with the heat-generating component.

21. One or more non-transitory computer-readable media comprising instructions to cause an electronic device, upon execution of the instructions by a controller of the electronic device, to:
identify a heat condition associated with a first heat-generating component of a plurality of heat-generating components; and
alternate, based on the heat condition, a cooling zone director between a first position associated with the first heat-generating component and a second position associated with a second heat-generating component of the plurality of heat-generating components with a frequency that is greater than a thermal time constant related to the first heat-generating component.

22. The one or more non-transitory computer-readable media of claim 21, wherein a fan is to cause air to move over the first heat-generating component when the cooling zone director is in the first position and the fan is to cause air to move over the second heat-generating component when the cooling zone director is in the second position.

23. The one or more non-transitory computer-readable media of claim 22, wherein the fan is a first fan and the heat condition is a failure of a second fan that is associated with the second one of the plurality of heat-generating components.

24. The one or more non-transitory computer-readable media of claim 21, wherein the electronic device is caused to alternate the cooling zone director from the first position to the second position based on an air pressure differential of the electronic device.

25. The one or more non-transitory computer-readable media of claim 21, wherein the electronic device is caused to identify a heat condition associated with an increased workload of the second heat-generating component.

26. The one or more non-transitory computer-readable media of claim 21, wherein the electronic device is a server.
